(19) United States
(12) Patent Application Publication
(10) Pub. No.: US 2025/0098239 A1
(43) Pub. Date: Mar. 20, 2025

(54) AIR GAP INSULATION IN PLACE OF GATE SPACERS

(71) Applicant: Intel Corporation, Santa Clara, CA (US)

(72) Inventors: Seda Cekli, Portland, OR (US); Makram Abd El Qader, Hillsboro, OR (US); Aaron D. Lilak, Beaverton, OR (US); Anh Phan, Beaverton, OR (US)

(73) Assignee: Intel Corporation, Santa Clara, CA (US)

(21) Appl. No.: 18/470,493

(22) Filed: Sep. 20, 2023

(51) Int. Cl. H01L 29/06; H01L 21/8234; H01L 27/088; H01L 29/08; H01L 29/423; H01L 29/778; H01L 29/786

(52) U.S. Cl. CPC H10D 62/118; H10D 30/47; H10D 30/6735; H10D 30/6757; H10D 62/151; H10D 84/0128; H10D 84/0149; H10D 84/038; H10D 84/83

(57) ABSTRACT

IC structures with air gap insulation in place of gate spacers are disclosed. An example IC structure includes a transistor comprising a channel region and a S/D region, a gate structure coupled to the channel region and comprising a gate electrode material and a first electrically conductive material, a S/D contact structure coupled to the S/D region and comprising a second electrically conductive material, a gap between the gate structure and the S/D contact structure, and a liner material over at least a portion of a sidewall of the region below the contact structure, the liner material comprising aluminum and oxygen.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component (e.g., of each transistor) is becoming increasingly significant.

### BRIEF DESCRIPTION OF THE DRAWINGS

Embodiments will be readily understood by the following detailed description in conjunction with the accompanying drawings.

FIG. 1 provides a perspective view of an example nanoribbon field-effect transistor (FET), according to some embodiments of the present disclosure.

FIG. 2 is a flow diagram of an example method for fabricating an IC structure with air gap insulation in place of gate spacers, in accordance with some embodiments.

FIGS. 3A-3N provide cross-sectional side views at various stages in the fabrication of an example IC structure according to the method of FIG. 2, in accordance with some embodiments.

FIGS. 4A-4B provide cross-sectional side views illustrating characteristic features that may be present in IC structures as a result of performing the method of FIG. 2, in accordance with some embodiments.

FIG. 5 is a top view of a wafer and dies that may include any of the IC structures disclosed herein, in accordance with any of the embodiments disclosed herein.

FIG. 6 is a side, cross-sectional view of an IC device that may include any of the IC structures disclosed herein, in accordance with any of the embodiments disclosed herein.

FIG. 7 is a side, cross-sectional view of an IC package that may include any of the IC structures disclosed herein, in accordance with various embodiments.

FIG. 8 is a side, cross-sectional view of an IC device assembly that may include any of the IC structures disclosed herein, in accordance with any of the embodiments disclosed herein.

FIG. 9 is a block diagram of an example electrical device that may include any of the IC structures disclosed herein, in accordance with any of the embodiments disclosed herein.

### DETAILED DESCRIPTION

Disclosed herein is a fabrication method and associated IC structures, and devices. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

As briefly described above, scaling down features in ICs has fueled the semiconductor industry's growth. Smaller features mean more functions on chips, boosting capacity. Optimizing fabrication and performance of each individual component is crucial in the pursuit of greater capacity. One factor limiting performance is capacitance. It can slow down the operation of transistors and other components, impacting speed and power consumption. High capacitance can also lead to crosstalk, which is unwanted interference between adjacent components.

Capacitance is a concern whenever two metal structures are placed in close proximity to each other in an IC. A prominent example is having a source contact and a drain contact on either side of a gate contact of a FET, since such contacts are metal structures. Conventional transistors employ gate spacers of solid dielectric materials to help isolate the gate contact from the source/drain (S/D) contacts. Gate spacers create a physical gap between the gate and the S/D contacts and help prevent unintended electrical interactions between these components, ensuring that the transistor functions as intended.

Since capacitance is directly proportional to the dielectric constant of the material between the plates of a capacitor, reducing the dielectric constant of gate spacers could result in reduced capacitance associated with the proximity of gate and S/D contacts. Air, being a gas, has a very low k-value that approximates the theoretical limit of 1.0. Therefore, when air is used as an insulator or to create gaps between conductive elements in ICs, it significantly reduces the capacitance compared to solid dielectric isolation.

Providing air gap insulation in place of gate spacers of transistors may provide one venue for optimizing performance of transistors and IC structures in which they are implemented. Being able to at least partially etch away the gate spacers once gate and S/D contacts have been formed, leaving air in their place, could provide tremendous benefits in terms of reduced capacitance. However, gate spacer etch possesses very high risk and challenges due to selectivity requirements and varying critical material exposure that can impact yield negatively.

Various embodiments of a fabrication method proposed herein may help improve on one or more challenges described above, e.g., may help reduce the risk and challenges associated with the etch of gate spacers, making air gap insulation in place of gate spacers feasible. IC structures with air gap insulation in place of gate spacers fabricated using the method described herein may possess several features characteristic of the use of the method. For example, in one aspect, an example IC structure includes a transistor comprising a channel region and a S/D region, a gate structure coupled to the channel region and comprising a gate electrode material and a first electrically conductive material, a S/D contact structure coupled to the S/D region and comprising a second electrically conductive material, a gap between the gate structure and the S/D contact structure, and a liner material over at least a portion of a sidewall of the region below the S/D contact structure, the liner material comprising aluminum and oxygen. The sidewall coverage can be adjustable dependent on the gate spacer removal amount needed. The gap may provide air gap insulation and may be in place of a gate spacer. As used herein, “air gap insulation in place of gate spacers” covers scenarios where gaps filled with air fully replace one or more gate spacers, scenarios where gaps filled with air partially replace one or more gate spacers, and where any of such gaps are filled with a gas other than air.

IC structures as described herein, in particular IC structures with air gap insulation in place of gate spacers, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with air gap insulation in place of gate spacers as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

A fabrication method for forming IC structures with air gap insulation in place of gape spacers, presented herein, may be carried out with transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surfaces. A confinement surface refers to a particular orientation of the channel surface that is confined by the gate field. Non-planar transistors potentially improve performance relative to transistors having a planar architecture, such as single-gate transistors.

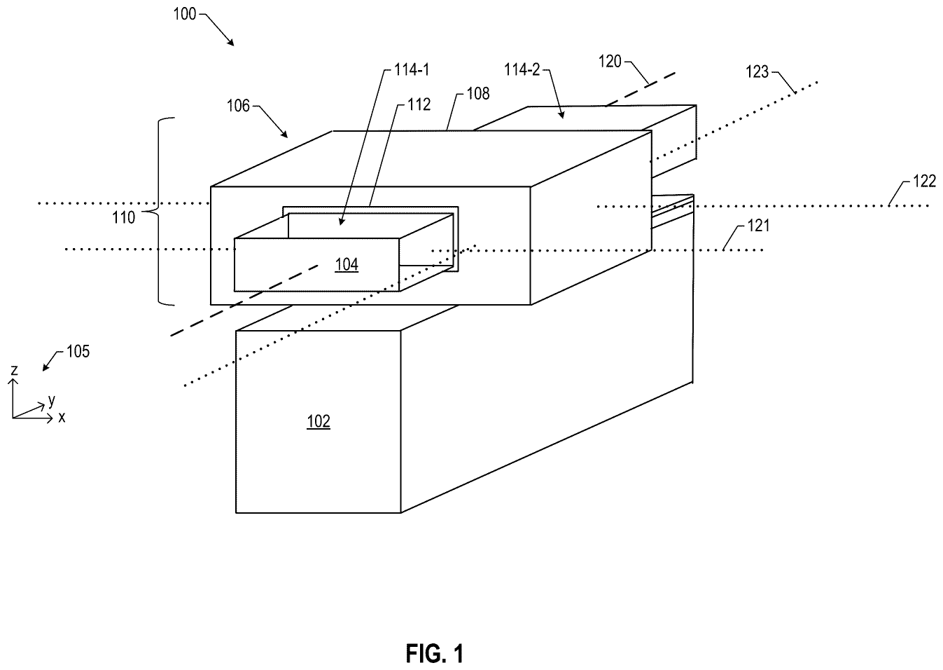

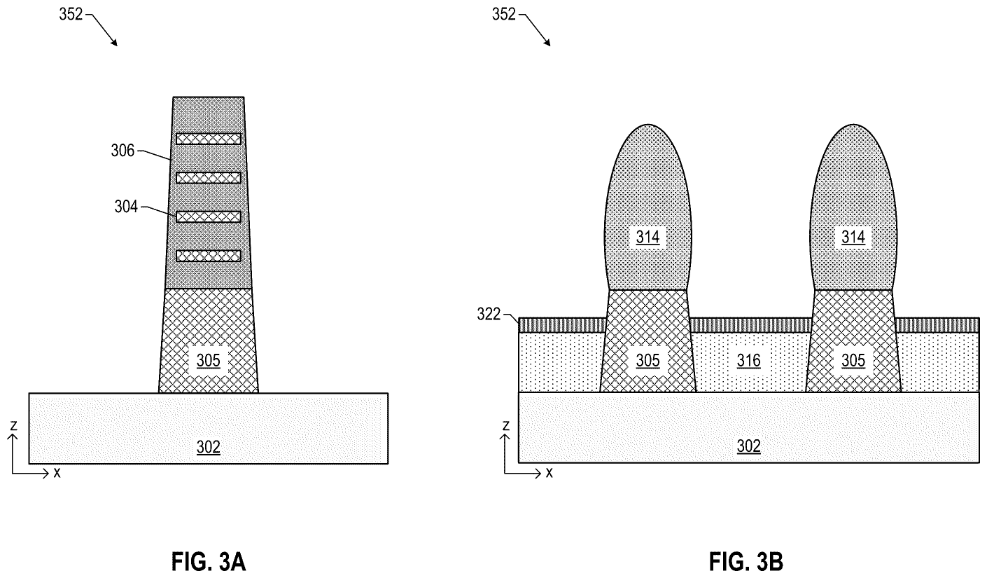

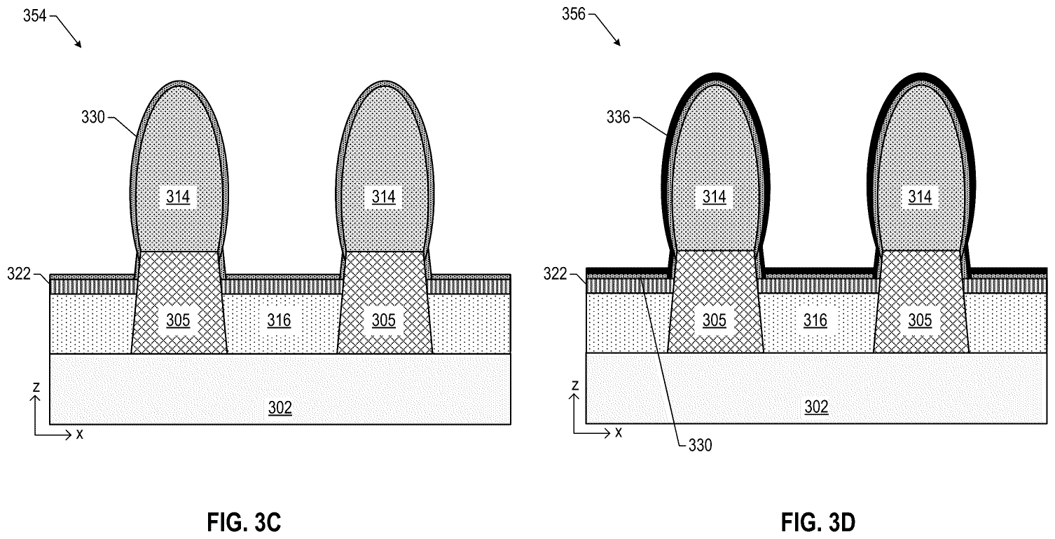

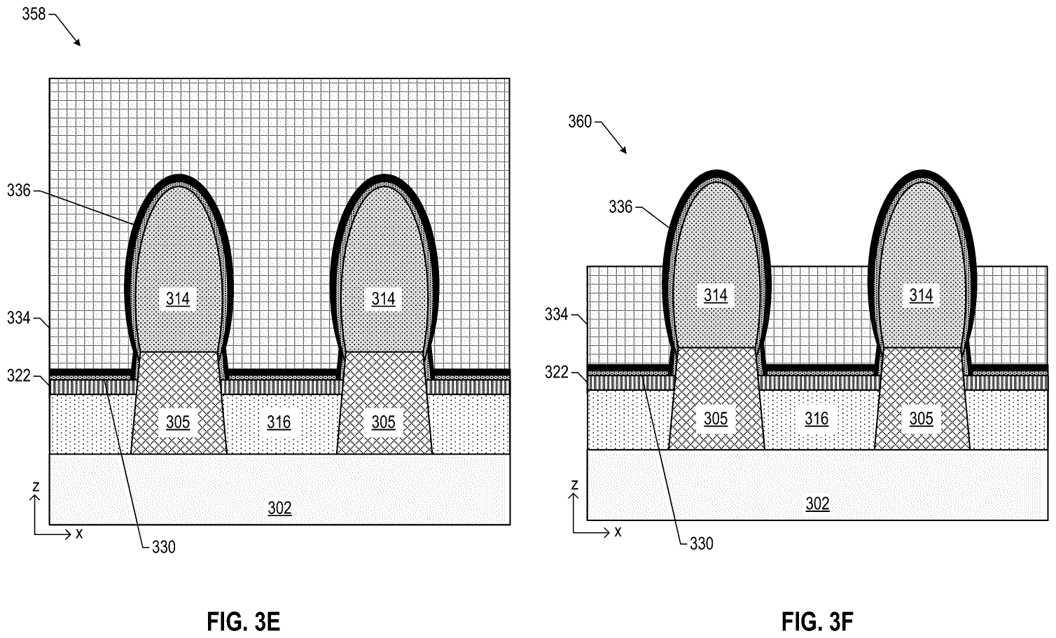

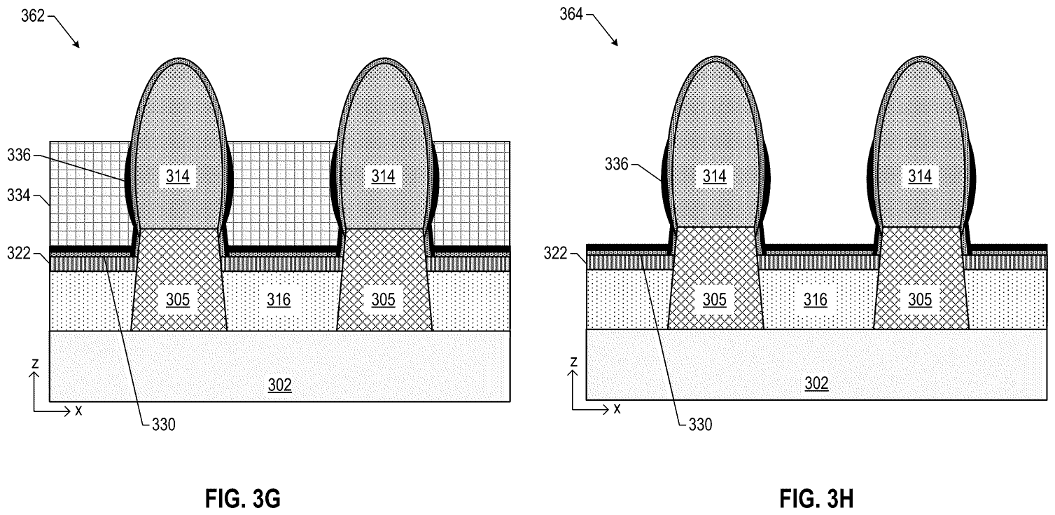

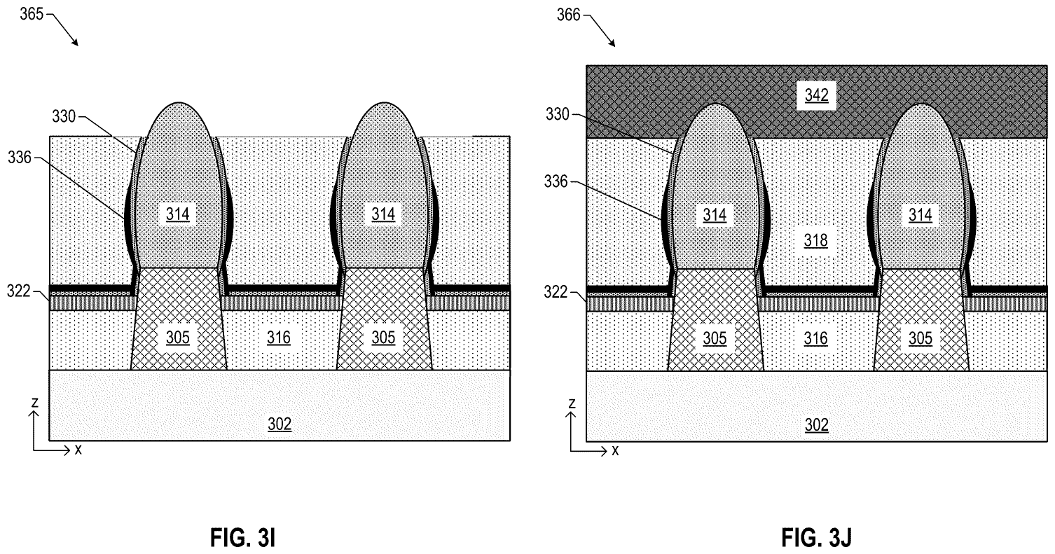

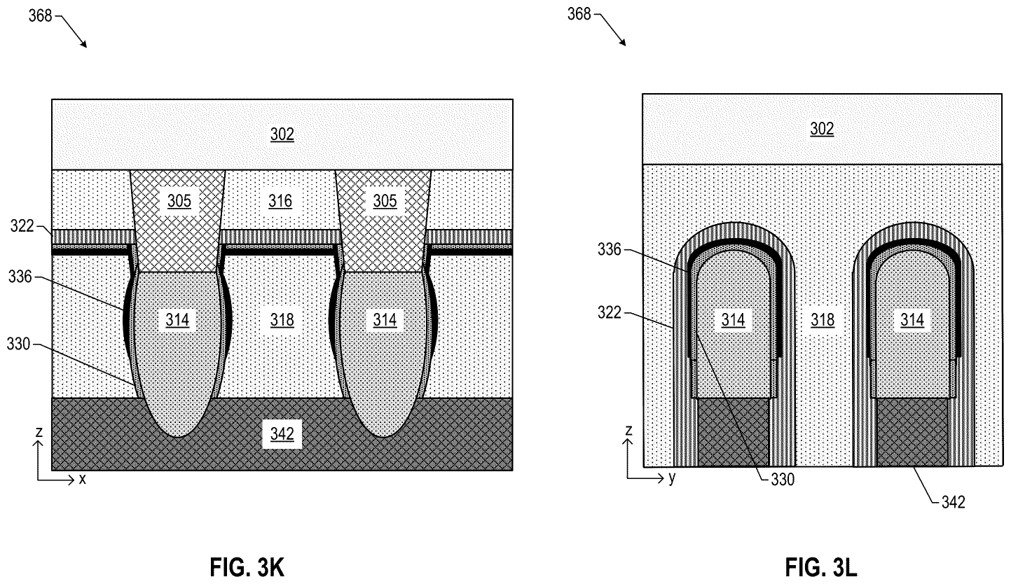

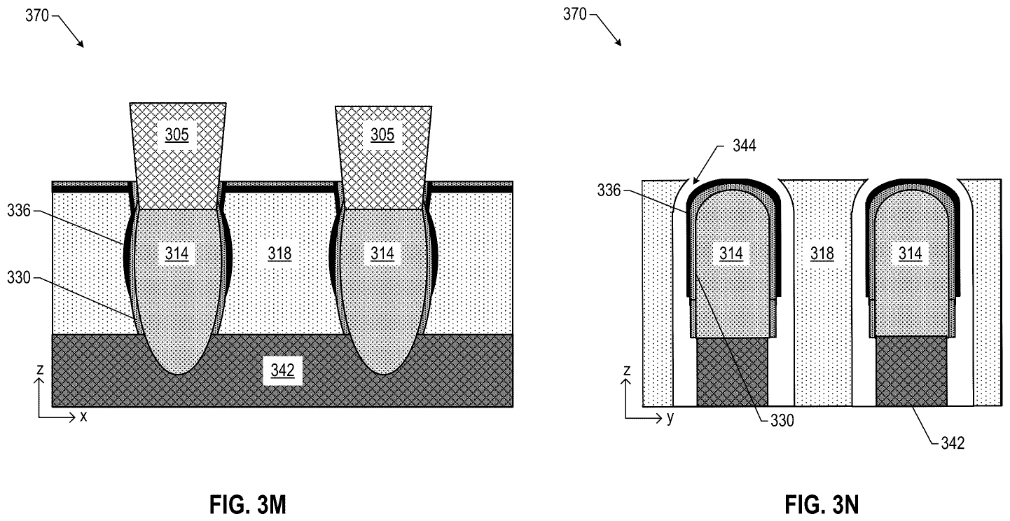

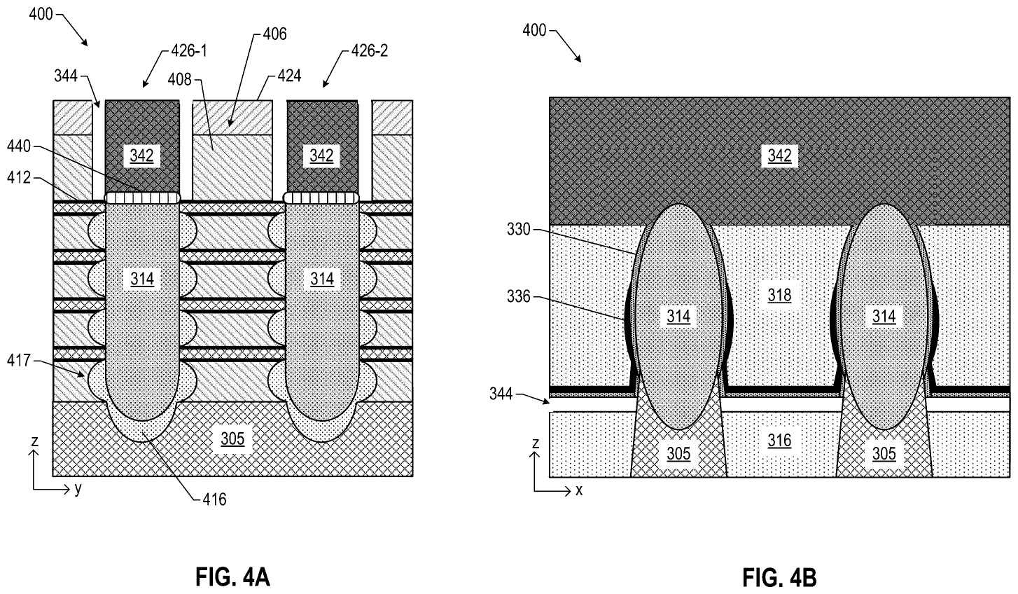

Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). Therefore, some IC structures illustrated herein show nanoribbon transistors as an example (e.g., IC structures shown in FIG. 1, FIGS. 3A-3N, and FIGS. 4A-4B), although the fabrication method described herein is not limited to such transistors.

As used herein, the term “nanoribbon” refers to an elongated structure of a semiconductor material having a longitudinal axis parallel to a support structure (e.g., a substrate, a die, a chip, or a wafer) over which such a structure is built. Typically, a length of a such a structure (i.e., a dimension measured along the longitudinal axis, shown in the present drawings to be along the y-axis of an example x-y-z coordinate system 105 shown in FIG. 1) is greater than each of a width (i.e., a dimension measured along the x-axis of the coordinate system 105) and a thickness/height (i.e., a dimension measured along the z-axis of the coordinate system 105). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain regions of a transistor provided on either side of the channel material.

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2, on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

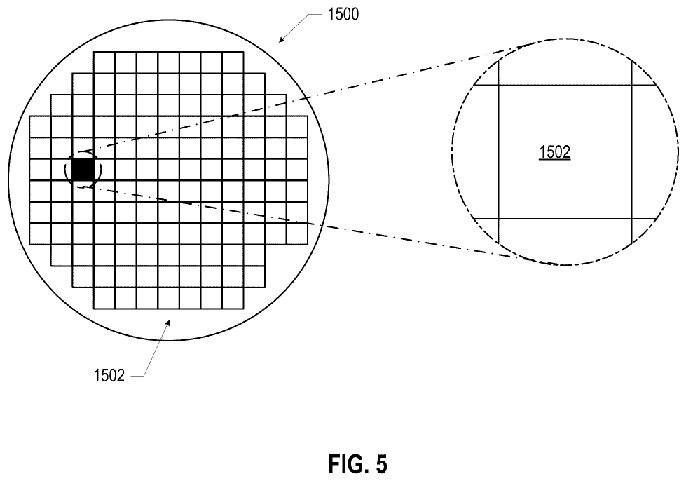

Implementations of the present disclosure may be formed or carried out on any suitable support 102, such as a substrate, a die, a wafer, or a chip. The support 102 may, e.g., be the wafer 1500 of FIG. 5, discussed below, and may be, or be included in, a die, e.g., the singulated die 1502 of FIG. 5, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. Although a few examples of materials from which the support 102 may be formed are described here, any material that may serve as a foundation upon which an IC structure with air gap insulation in place of gate spacers as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another, e.g., as is shown in FIGS. 3A-3N showing IC structures that may be examples of the IC structure 100. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of the coordinate system 105 shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 102 and in a direction perpendicular to the longitudinal axis 120 of the nanoribbon 104, e.g., along the x-axis of the coordinate system 105) may be at least about 3 times larger than a height of the nanoribbon 104 (i.e., a dimension measured in a plane perpendicular to the support 102, e.g., along the z-axis of the coordinate system 105), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary IlI-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front-end components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a PMOS transistor or an NMOS transistor. For a PMOS transistor, gate electrode materials that may be used in different portions of the gate electrode material 108 may include, but are not limited to, ruthenium, palladium, platinum, cobalt, nickel, and conductive metal oxides (e.g., ruthenium oxide). For an NMOS transistor, gate electrode materials that may be used in different portions of the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabricate of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided above.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even when doped to realize threshold voltage tuning as described herein, the channel portions of transistors typically include semiconductor materials with doping concentrations significantly smaller than those of the S/D regions 114, e.g., at least 100 times smaller or at least 1000 times smaller.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110). For example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass. In another example, although not specifically illustrated in FIG. 1, a solid dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. Embodiments of the present disclosure aim to replace at least portions of such a dielectric spacer with air, to provide IC structures with air gap insulation in place of gate spacers.

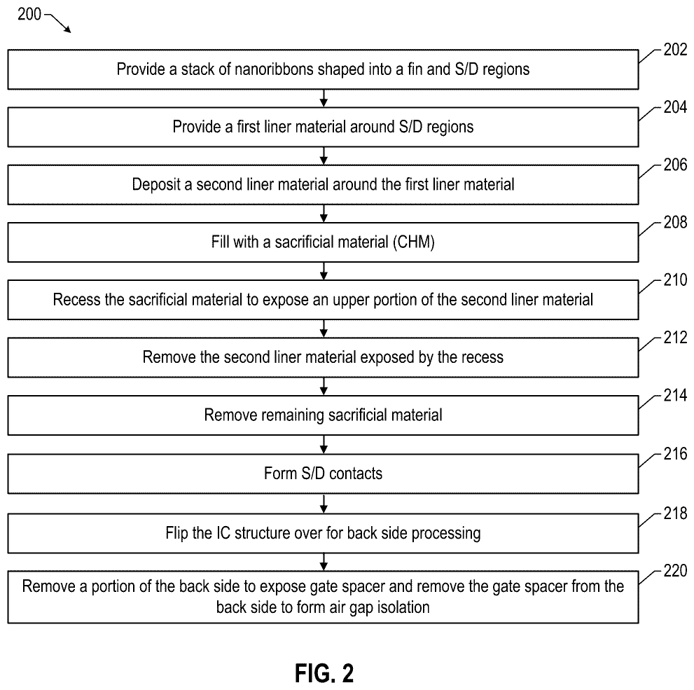

FIG. 2 is a flow diagram of an example method 200 for fabricating an IC structure with air gap insulation in place of gate spacers, in accordance with some embodiments. FIGS. 3A-3N provide cross-sectional side views at various stages in the fabrication of an example IC structure according to the method of FIG. 2, in accordance with some embodiments. Different ones of FIGS. 3A-3N illustrate cross-sectional side views of IC structures in vertical planes (i.e., planes perpendicular to the support 102) along axes 121, 122, and 123 shown in FIG. 1.

Although the operations of the method 200 are illustrated once each and in a particular order, the operations may be performed in any suitable order and repeated as desired. For example, one or more operations may be performed in parallel to fabricate multiple IC structures with air gap insulation in place of gate spacers substantially simultaneously. In another example, the operations may be performed in a different order to reflect the structure of an IC device in which an IC structure with air gap insulation in place of gate spacers will be implemented.

In addition, the example fabricating method 200 may include other operations not specifically shown in FIG. 2, such as various cleaning or planarization operations as known in the art. For example, in some embodiments, a support 302, as well as layers of various other materials subsequently deposited thereon, may be cleaned prior to, after, or during any of the processes of the method 200 described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method 200 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

The method 200 may begin with a process 202 that includes providing a stack of nanoribbons shaped into a fin over a support and forming S/D regions extending through the stack. An IC structure 352 of FIGS. 3A-3B illustrates an example result of the process 202, where FIG. 3A illustrates a cross-section along the axis 122 (i.e., a fin cut on gate), while FIG. 3B illustrates a cross-section along the axis 121 (i.e., a fin cut in S/D regions). FIG. 3B and subsequent drawings in the same plane illustrate two fins, e.g., two arrangements as shown in FIG. 1 provided parallel to one another. The IC structure 352 illustrates a support 302, a stack of released nanoribbons 304 over the support 302, a subfin 305 below the nanoribbons 304, a gate stack 306, a gate spacer 322, and S/D regions 314. The support 302, the nanoribbons 304, and the S/D regions 314 may be examples of, respectively, the support 102, the nanoribbons 104, and the S/D regions 114 described above. The gate stack 306 may either include a gate electrode material 108 and a gate insulator material 112 as described above with reference to the gate stack 106, or may be a dummy gate stack as known in the art, depending on when the actual gate stack 106 is fabricated in the process 200, which is outside of the scope of the present disclosure.

FIG. 3A illustrates that a plurality of nanoribbons 304 may be stacked above one another. FIG. 3A and some of the subsequent drawings illustrate four nanoribbons 304 in a stack, but, in other embodiments, a stack of nanoribbons 304 may include any other number of two or more nanoribbons 304. The material composition of different stacks of nanoribbons 304 may be different depending on whether the stacks are to implement NMOS or PMOS transistors, in line with the descriptions provided above. The nanoribbons 304 may be “released” in that openings were previously formed around channel portions of the nanoribbons 304, in which openings the gate stack 306 as described above is subsequently provided. FIG. 3B also illustrates gate spacers 322. The gate spacers 322 may be configured to provide separation between the gate stack 306 and future S/D contacts of transistors 110 provided along the stack of the nanoribbons 304 and could be made of a low-k dielectric material, some examples of which have been provided above. As a result of performing the method 200, some or all of the gate spacers 322 between the gate contacts and S/D contacts may be removed, as will be shown in subsequent drawings. FIG. 3B further illustrates an insulator material 316 that may enclose sidewalls of the subfins 305. The insulator material 316 may include any suitable insulator material e.g., one or more materials described with reference to the ILD materials. FIG. 3B illustrates S/D regions 314 extending through the stack of nanoribbons 304. The stack of released nanoribbons 304 provided over the support 302, the gate stack 306, and the S/D regions 314 may be formed according to any of the techniques known in the art.

The method 200 may then proceed with a process 204, in which a first liner material is deposited around the S/D regions formed in the process 202 and other exposed surfaces. An IC structure 354 of FIG. 3C illustrates an example result of the process 204. FIG. 3C illustrates a cross-section along the axis 121. As shown in FIG. 3C, a first liner material 330 may line the S/D regions 314 provided in the IC structure 352 of FIGS. 3A-3B. The first liner material 330 may include any material that may protect the S/D regions from subsequent fabrications processes such as cure, anneal, deposition, etch, etc. In some embodiments, the first liner material 330 may be a material that can hermetically seal the S/D regions to reduce effects of subsequent fabrication steps and to reduce possibilities for oxidation, which could otherwise change the composition of the materials in the S/D regions and degrade carrier mobility. For example, in some embodiments, the first liner material 330 may include silicon and nitrogen (e.g., the first liner material 330 may be silicon nitride). The first liner material 330 may be deposited using any suitable deposition technique, such as any suitable conformal deposition technique such as atomic layer deposition (ALD). A thickness of the first liner material 330 may be between about 1 nanometer and about 8 nanometers in some embodiments, including all values and ranges therein, e.g., between about 1 nanometer and 5 nanometers, or between about 1 nanometer and 3 nanometers.

The method 200 may then proceed with a process 206, in which a second liner material is deposited around the first liner material deposited in the process 204 and other exposed surfaces. An IC structure 356 of FIG. 3D illustrates an example result of the process 206. FIG. 3D illustrates a cross-section along the axis 121. As shown in FIG. 3D, a second liner material 336 may line the first liner material 330 provided in the IC structure 354 of FIG. 3C. The second liner material 336 may include any material that is sufficiently etch-selective with respect to the etchants used subsequently to remove the gate spacer 322 so that it may act as a protective layer for protecting the S/D regions 314 from being etched. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the second liner material 336 may include aluminum and oxygen (e.g., the second liner material 336 may be aluminum oxide). The second liner material 336 may be deposited using any suitable deposition technique, such as any suitable conformal deposition technique such as ALD. A thickness of the second liner material 336 may be between about 1 nanometer and about 10 nanometers in some embodiments, including all values and ranges therein, e.g., between about 1 nanometer and 5 nanometers, or between about 1 nanometer and 3 nanometers.

In a process 208 of the method 200, a sacrificial material may be deposited in all open spaces around the S/D regions 314 lined with the first liner material 330 and the second liner material 336. An IC structure 358 of FIG. 3E illustrates an example result of the process 208. FIG. 3E illustrates a cross-section along the axis 121. The IC structure 358 is substantially the same as the IC structure 356, but further showing a sacrificial material 334. In various embodiments, the sacrificial material 334 may include any suitable material that may later be removed. For example, the sacrificial material 334 may be any suitable organic material, e.g., any suitable carbon-based material, that may later be removed by ashing.

The method 200 may further include a process 210, in which the sacrificial material may be recessed to expose an upper portion of the second liner material deposited in the process 206. An IC structure 360 of FIG. 3F illustrates an example result of the process 210. FIG. 3F illustrates a cross-section along the axis 121. The IC structure 360 is substantially the same as the IC structure 358, but showing that the sacrificial material 334 is recessed to expose a portion of the second liner material 336. Any suitable etching technique, e.g., a dry etch, such as radio frequency (RF) reactive ion etch (RIE) or inductively coupled plasma (ICP) RIE could be used to remove the sacrificial material 334. In some embodiments, the etch performed in the process 210 may include an anisotropic etch, using etchants in a form of e.g., chemically active ionized gas (i.e., plasma) using e.g., bromine (Br) and chloride (CI) based chemistries. In some embodiments, during the etch of the process 210, the IC structure may be heated to elevated temperatures, e.g., to temperatures between about room temperature and 200 degrees Celsius, including all values and ranges therein, to promote that byproducts of the etch are made sufficiently volatile to be removed from the surface.

The method 200 may then proceed with a process 212, in which the second liner material exposed by the recess in the sacrificial material is removed. An IC structure 362 of FIG. 3G illustrates an example result of the process 212. FIG. 3G illustrates a cross-section along the axis 121. The IC structure 362 is substantially the same as the IC structure 360, but showing that the second liner material 336 exposed by the recess in the sacrificial material 334 is removed. A wet etch may be used in the process 212 to remove the exposed second liner material 336.

The method 200 may further include a process 214, in which the remaining sacrificial material is removed. An IC structure 364 of FIG. 3H illustrates an example result of the process 214. FIG. 3H illustrates a cross-section along the axis 121. The IC structure 364 is substantially the same as the IC structure 362, but showing that the sacrificial material 334 is completely removed. Any suitable technique may be used to remove the sacrificial material 334, such as ashing.

The method 200 may then proceed with a process 216, in which S/D contacts are fabricated. the upper portion of the first liner material exposed by the removal of the upper portion of the second liner material may be removed and an insulator material may be deposited to fill open spaces. An IC structure 365 of FIG. 3I illustrates an example intermediate result of the process 216, and an IC structure 366 of FIG. 3J illustrates an example final result of the process 216. Both FIG. 3I and FIG. 3J illustrate cross-sections along the axis 121. The IC structure 365 is substantially the same as the IC structure 364, but showing that an insulator material 318 may be deposited to fill open spaces and that an upper portion of the first liner material 330 exposed by the recess in the second liner material 336 may be removed. Any suitable etching technique, e.g., a dry etch as described above, could be used to remove the exposed first liner material 330, possibly in combination with patterning. The IC structure 366 is substantially the same as the IC structure 366, but showing an electrically conductive material 342 may be deposited into openings above the S/D regions 314 to form S/D contacts. Another view of S/D contacts is shown in FIG. 4A, illustrating further how the electrically conductive material 342 is deposited into openings above the S/D regions 314 to form S/D contacts 426, individually labeled in FIG. 4A as S/D contacts 426-1 and 426-2. FIG. 4A also illustrates how a layer of an interface material such as titanium may be first deposited onto the S/D regions 314 prior to the deposition of the electrically conductive material 342, in order to form an interface 440 at the bottom of S/D contacts. The interface 440 of FIG. 4A is not shown in FIG. 3J and other drawings in order to not clutter these drawings. The insulator material 318 may include any suitable insulator material, e.g., one or more materials described with reference to the ILD materials and may be deposited in the process 206 using techniques such as ALD or chemical vapor deposition (CVD). In some embodiments, the insulator material 318 may have substantially the same material composition as the insulator material 316. In other embodiments, material compositions of the insulator material 318 and the insulator material 316 may be different. The electrically conductive material 342 may include any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals. The electrically conductive material 342 may be deposited using a technique such as ALD, CVD, plasma enhanced CVD (PECVD), or/and physical vapor deposition (PVD) processes such as sputter. The electrically conductive material 342 will form contacts to S/D regions 314 and, therefore, the process 216 of providing the electrically conductive material 342 may be referred to as “S/D contact metallization.”

The method 200 may further include a process 218, the IC structure of the previous process is flipped over so that it is ready for backside processing. An IC structure 368 of FIGS. 3K-3L illustrates an example result of the process 218. The IC structure 368 of FIG. 3K is substantially the same as the IC structure 366 of FIG. 3J but shown upside down, showing a cross-section along the axis 121. On the other hand, FIG. 3L illustrates the IC structure 368 in a cross-section along the axis 123 of FIG. 1.

The method 200 may then proceed with a process 220, in which a portion of the back side is removed to expose an upper portion of the gate spacer from the back side and then use it as an access point to etch the gate spacer from the back side. An IC structure 370 of FIGS. 3M-3N illustrates an example result of the process 220. The IC structure 370 of FIG. 3M is substantially the same as the IC structure 368 of FIG. 3K, showing a cross-section along the axis 121, but with the gate spacer 322, the insulator material 316, and a portion of the back side of the IC structure 368 being removed. The IC structure 370 of FIG. 3N is substantially the same as the IC structure 368 of FIG. 3L, showing a cross-section along the axis 123, but also with the gate spacer 322, the insulator material 316, and a portion of the back side of the IC structure 368 being removed. In some embodiments, the process 220 may be a two-step process. In the first step, a portion of the back side, e.g., the support 302, may be removed from the back side by a process such as grinding. In the second step, the insulator material 316 may be removed to expose the gate spacer 322. After that, some or all of the gate spacer 322 may be removed. FIG. 3N illustrates openings 344 (which may also be referred to as “gaps”) that result from the gate spacer 322 being removed. These openings extend to the gate stack 306 (as shown in FIG. 4A), providing air gap isolation between the electrically conductive materials of the gate contact and the electrically conductive materials of the S/D contacts on either side of the gate contact. A wet etch process may be used in the process 220 to remove the gate spacer 322 without substantially etching other materials in its vicinity. As shown in FIG. 3N, the material of the S/D regions 314 may remain intact because it is protected from the etch of the process 370 by the second liner material 336 that encapsulates it.

Performing the method 200 may result in several features in the final IC structures that are characteristic of the use of the method 200. Such features are illustrated in FIGS. 4A-4B.

FIG. 4A illustrates an IC structure 400 in a cross-section along the axis 120 of FIG. 1 after gate contact and S/D contacts have been formed and after openings 344 have been formed, using the method 200, by removing some or all of the gate spacers 322 that were previously in the place of the openings 344. FIG. 4A illustrates a gate stack 406 that includes a gate electrode material 408 and a gate insulator material 412. The gate stack 406, the gate electrode material 408, and the gate insulator material 412 may be examples of, respectively, the gate stack 106, the gate electrode material 108, and the gate insulator material 112, described above. FIG. 4A further illustrates an electrically conductive material 424 that may be provided over the gate electrode material 408 and may serve as a gate line for providing electrical conductivity to the gate of the transistor based on the stack of nanoribbons 304 (e.g., by being in electrically conductive contact with the gate electrode material 408). The electrically conductive material 424 may include any suitable electrically conductive material, such as any of those described above, and may be deposited using a technique such as ALD, CVD, PECVD, or/and PVD processes such as sputter. A gate structure that includes the gate electrode material 408 and the electrically conductive material 424, e.g., as shown in FIG. 4A, may be referred to as a “gate contact” of the transistor of the IC structure 400.

FIG. 4A further illustrates an electrically conductive material 342 deposited into openings above the S/D regions 314 to form S/D contacts 426, individually labeled in FIG. 4A as S/D contacts 426-1 and 426-2. In some embodiments, prior to depositing the electrically conductive material 342 into the openings for future S/D contacts 426, a layer of an interface material may be deposited at the bottom of the openings. In some embodiments, the interface material may be deposited directly onto the material of the S/D regions 314. Subsequently, the interface material may interact with the material of S/D regions 314, forming an interface 440 at the bottom of the openings for future S/D contacts 426. For example, if the interface material is titanium and the S/D regions 314 included silicon, then the interface 440 may be a layer of titanium silicide. Providing the interface 440 at the bottom of the openings for future S/D contacts 426 may help improve conductivity of S/D contacts 426, e.g., by reducing contact resistance.

FIG. 4A illustrates S/D regions 314 extending through the stack of nanoribbons 304, as well as an insulator material 416 to electrically insulate/separate the S/D regions 314 from the gate electrode material 408 of the gate stack 406 and from the subfin 305. Portions of the insulator material 416 extending from the respective side of the S/D regions 314 into the openings between the nanoribbons 304 where the gate stack 406 is provided may be referred to as “dimples” 417. In other embodiments, shape of the dimples 417 may be different from that shown in FIG. 4A, as long as the dimples 417 of the insulator material 416 provide electrical isolation between the S/D regions 314 and the gate electrode material 408. The insulator material 416 may include any suitable insulator material, e.g., one or more materials described with reference to the ILD materials.

One feature in FIG. 4A that is indicative of the use of the method 200 is the presence of the openings 344 between the gate contact that includes the gate electrode material 408 and the electrically conductive material 424 and S/D contacts 426 on either side of the gate contact. In some embodiments, the distance between the gate contact and either one of the S/D contacts 426 may be between about 3 nanometers and 50 nanometers, e.g., between about 3 nanometers and 15 nanometers, or between about 3 nanometers and 10 nanometers. In some embodiments, at least a portion of a volume between the gate contact and either one of the S/D contacts 426 is filled with air, thus providing air gap insulation. Another feature that is indicative of the use of the method 200 is shown in FIG. 4B. FIG. 4B illustrates the same IC structure 400 as in FIG. 4A but in a cross-section along the axis 121 of FIG. 1. In particular, presence of the second liner material 336 that is recessed from the top of S/D regions 314 and below the electrically conductive material 342 of the S/D contacts 426 is indicative of the use of the method 200 as described above.

IC structures with air gap insulation in place of gate spacers as described herein (e.g., as described with reference to FIGS. 1-4) may be used to implement any suitable components. For example, in various embodiments, IC structures described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC structures with air gap insulation in place of gate spacers disclosed herein, e.g., the IC structures 370 or 400, may be included in any suitable electronic component. FIGS. 5-9 illustrate various examples of apparatuses that may include one or more IC structures disclosed herein.

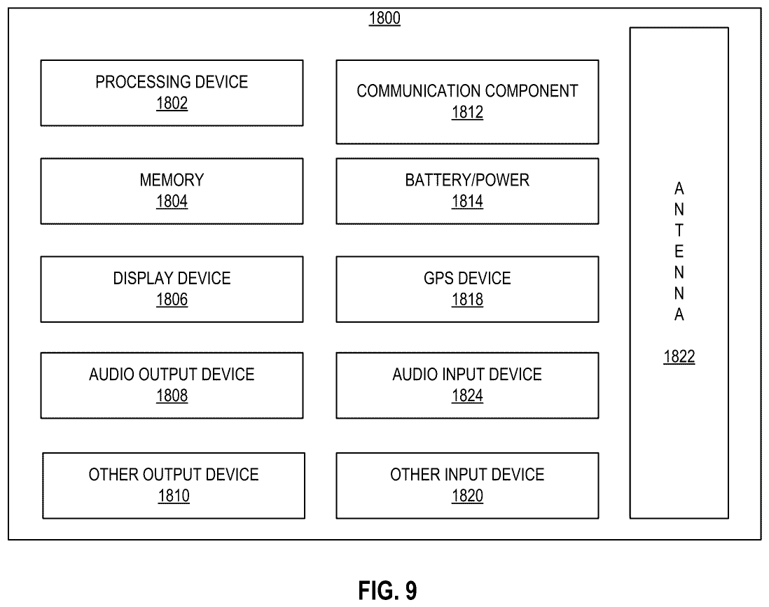

FIG. 5 is a top view of a wafer 1500 and dies 1502 that may include one or more IC structures with air gap insulation in place of gate spacers in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more of the IC structures 370 or 400 and/or supporting circuitry to route electrical signals to the transistors of these IC structures, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array.

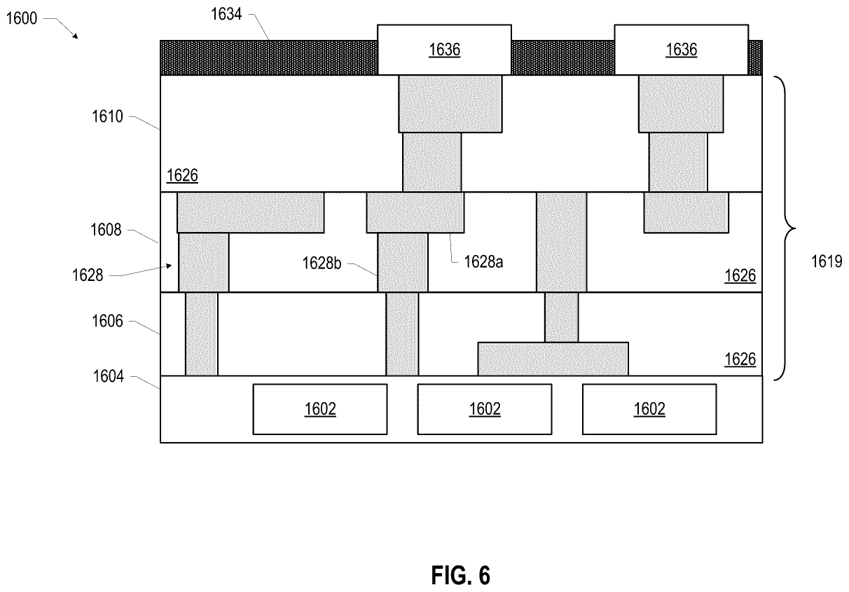

FIG. 6 is a side, cross-sectional view of an IC device 1600 that may include one or more IC structures with air gap insulation in place of gate spacers in accordance with any of the embodiments disclosed herein. One or more of the IC devices 1600 may be included in one or more dies 1502 (FIG. 5). The IC device 1600 may include a device region 1604 including one or more IC structures 1602, where any of the IC structures 1602 may include any of the IC structures with air gap insulation in place of gate spacers, disclosed herein, e.g., the IC structures 370 or 400. The device region 1604 may further include electrical contacts to the gate and S/D contacts of the transistors included in the device region 1604.

Electrical signals, such as power and/or input/output (I/O) signals, may be routed to and/or from the devices (e.g., the transistors) of the device region 1604 through one or more interconnect layers disposed on the device region 1604 (illustrated in FIG. 6 as interconnect layers 1606, 1608, and 1610). For example, electrically conductive features of the device region 1604 (e.g., the gate electrode material 408, the electrically conductive material 342, and the electrically conductive material 424 of the IC structure 400) may be electrically coupled with the interconnect structures 1628 of the interconnect layers 1606, 1608, and 1610. The one or more interconnect layers 1606, 1608, and 1610 may form a metallization stack (also referred to as an “ILD stack”) 1619 of the IC device 1600.

The interconnect structures 1628 may be arranged within the interconnect layers 1606, 1608, and 1610 to route electrical signals according to a wide variety of designs (in particular, the arrangement is not limited to the particular configuration of interconnect structures 1628 depicted in FIG. 6). Although a particular number of interconnect layers 1606, 1608, and 1610 is depicted in FIG. 6, embodiments of the present disclosure include IC structures having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of a support, e.g., the support 102, upon which the device region 1604 is formed. For example, the lines 1628a may route electrical signals in a direction in and out of the page from the perspective of FIG. 6. The vias 1628b may be arranged to route electrical signals in a direction of a plane that is substantially perpendicular to the surface of the support 102 upon which the device region 1604 is formed. In some embodiments, the vias 1628b may electrically couple lines 1628a of different interconnect layers 1606, 1608, and 1610 together.

The interconnect layers 1606, 1608, and 1610 may include a dielectric material 1626 disposed between the interconnect structures 1628, as shown in FIG. 6. In some embodiments, the dielectric material 1626 disposed between the interconnect structures 1628 in different ones of the interconnect layers 1606, 1608, and 1610 may have different compositions; in other embodiments, the composition of the dielectric material 1626 between different interconnect layers 1606, 1608, and 1610 may be the same.

A first interconnect layer 1606 may be formed above the device region 1604. In some embodiments, the first interconnect layer 1606 may include lines 1628a and/or vias 1628b, as shown. The lines 1628a of the first interconnect layer 1606 may be coupled with contacts (e.g., contacts to the S/D regions 114 of the IC structures with air gap insulation in place of gate spacers) of the device region 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device region 1604) may be thicker.

The IC device 1600 may include a solder resist material 1634 (e.g., polyimide or similar material) and one or more conductive contacts 1636 formed on the interconnect layers 1606, 1608, and 1610. In FIG. 6, the conductive contacts 1636 are illustrated as taking the form of bond pads. The conductive contacts 1636 may be electrically coupled with the interconnect structures 1628 and configured to route the electrical signals of the transistor(s) of the device region 1604 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606, 1608, and 1610; for example, the conductive contacts 1636 may include other analogous features (e.g., posts) that route the electrical signals to external components.

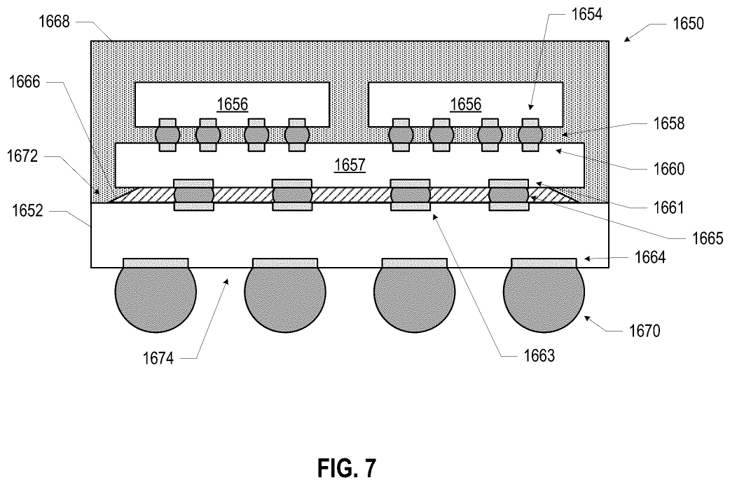

FIG. 7 is a side, cross-sectional view of an example IC package 1650 that may include one or more IC structures with air gap insulation in place of gate spacers in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects 1628 discussed above with reference to FIG. 6.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 7 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 7 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

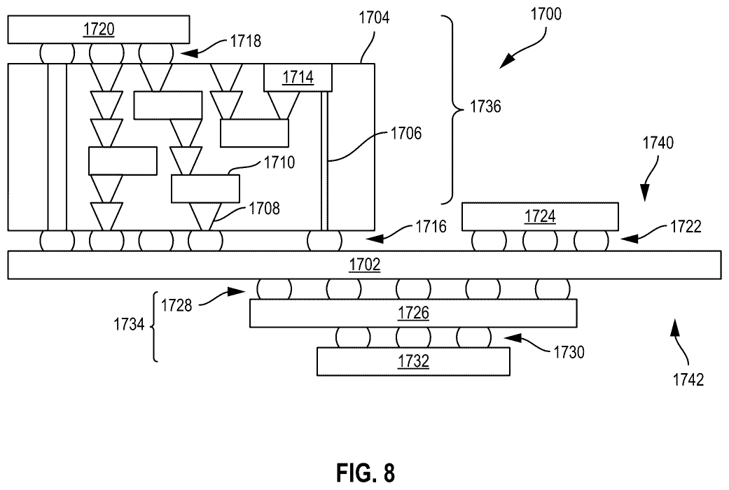

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 7 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 8.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 7 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 7, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 8 is a side, cross-sectional view of an IC device assembly 1700 that may include one or more IC packages or other electronic components (e.g., a die) including one or more IC structures with air gap insulation in place of gate spacers in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 7 (e.g., may include one or more IC structures with air gap insulation in place of gate spacers).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 5), an IC device (e.g., the IC device 1600 of FIG. 6), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 8, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example electrical device 1800 that may include one or more IC structures with air gap insulation in place of gate spacers in accordance with any of the embodiments disclosed herein. For example, any suitable ones of the components of the electrical device 1800 may include one or more of the IC device assemblies 1700, IC packages 1650, IC structures 1600, or dies 1502 disclosed herein. A number of components are illustrated in FIG. 9 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 9, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure that includes a transistor including a channel region and a region including a doped semiconductor material, where the region is either a source region or a drain region of the transistor; a gate structure coupled to the channel region, where the gate structure includes a gate electrode material and a first electrically conductive material; a contact structure coupled to the region, where the contact structure includes a second electrically conductive material; a gap between at least a portion of the gate structure and at least a portion of the contact structure; and a liner material over at least a portion of a sidewall of the region below the contact structure, the liner material including aluminum and oxygen.

Example 2 provides the IC structure according to example 1, where a thickness of the liner material is less than a bout 5 nanometers.

Example 3 provides the IC structure according to examples 1 or 2, where the liner material is a first liner material, and the IC structure further includes a second liner material over at least a portion of the sidewall of the region below the contact structure.

Example 4 provides the IC structure according to example 3, where the second liner material includes nitrogen.

Example 5 provides the IC structure according to example 4, where the second liner material further includes silicon.

Example 6 provides the IC structure according to any one of examples 3-5, where the second liner material is between the region and the first liner material.

Example 7 provides the IC structure according to any one of examples 3-6, where the second liner material is in contact with the region.

Example 8 provides the IC structure according to any one of examples 3-7, where the second liner material is in contact with the first liner material.

Example 9 provides the IC structure according to any one of examples 3-8, where a thickness of the second liner material is less than about 5 nanometers.

Example 10 provides the IC structure according to any one of the preceding examples, further including an interface material between the second electrically conductive material and the region.

Example 11 provides the IC structure according to example 10, where interface material includes titanium.

Example 12 provides the IC structure according to example 10, where the doped semiconductor material includes silicon and the interface material includes titanium and silicon (e.g., titanium silicide).

Example 13 provides the IC structure according to any one of the preceding examples, where the transistor is a nanoribbon transistor.

Example 14 provides an IC structure that includes a first semiconductor material having a dopant concentration of about 10e21 dopants per cubic centimeter; a second semiconductor material having a dopant concentration that is at least 100 times smaller than the dopant concentration of the first semiconductor material; a first contact structure coupled to the first semiconductor material, where the first contact structure includes a first electrically conductive material; a second contact structure coupled to the second semiconductor material, where the second contact structure includes a second electrically conductive material, where a distance between the first contact structure and the second contact structure is between about 3 nanometers and 50 nanometers, and at least a portion of a volume between the first contact structure and the second contact structure is filled with air; and a material over at least a portion of a sidewall of the first semiconductor material below the first contact structure, the material including aluminum and oxygen.

Example 15 provides the IC structure according to example 14, further including a transistor, where the first semiconductor material is either a source region or a drain region of the transistor.

Example 16 provides the IC structure according to example 15, where the second semiconductor material is a channel region of the transistor.

Example 17 provides the IC structure according to any one of examples 14-16, where the thickness of the material including aluminum and oxygen is below about 5 nanometers.

Example 18 provides the IC structure according to any one of examples 14-17, further including a material including silicon and nitrogen, where the material including silicon and nitrogen is between the first semiconductor material and the material including aluminum and oxygen.

Example 19 provides a method of fabricating an IC structure, the method including providing a first semiconductor material having a dopant concentration of about 10e21 dopants per cubic centimeter; providing a second semiconductor material having a dopant concentration that is at least 100 times smaller than the dopant concentration of the first semiconductor material; providing a first contact structure coupled to the first semiconductor material, where the first contact structure includes a first electrically conductive material; providing a second contact structure coupled to the second semiconductor material, where the second contact structure includes a second electrically conductive material, where a distance between the first contact structure and the second contact structure is between about 3 nanometers and 50 nanometers, and at least a portion of a volume between the first contact structure and the second contact structure is filled with air; and providing a material over at least a portion of a sidewall of the first semiconductor material below the first contact structure, the material including aluminum and oxygen.

Example 20 provides the method according to example 19, where a thickness of the material including aluminum and oxygen is below about 5 nanometers.

Example 21 provides the method according to any one of examples 19-20, where the IC structure is an IC structure according to any one of the preceding examples.

Example 22 provides an IC package that includes an IC die including an IC structure according to any one of examples 1-18; and a further IC component, coupled to the IC die.

Example 23 provides the IC package according to example 22, where the further IC component includes a package substrate.

Example 24 provides the IC package according to example 22, where the further IC component includes an interposer.

Example 25 provides the IC package according to example 22, where the further IC component includes a further IC die.

Example 26 provides a computing device that includes a carrier substrate and an IC structure coupled to the carrier substrate, where the IC structure is an IC structure according to any one of examples 1-18, or the IC structure is included in the IC package according to any one of examples 22-25.

Example 27 provides the computing device according to example 26, where the computing device is a wearable or handheld computing device.

Example 28 provides the computing device according to examples 26 or 27, where the computing device further includes one or more communication chips.

Example 29 provides the computing device according to any one of examples 26-28, where the computing device further includes an antenna.

Example 30 provides the computing device according to any one of examples 26-29, where the carrier substrate is a motherboard.

Example 31 provides the IC structure according to any one of examples 1-18, where the IC structure includes or is a part of a central processing unit.

Example 32 provides the IC structure according to any one of examples 1-31, where the IC structure includes or is a part of a memory device, e.g., a high-bandwidth memory device.

Example 33 provides the IC structure according to any one of examples 1-32, where the IC structure includes or is a part of a logic circuit.

Example 34 provides the IC structure according to any one of examples 1-33, where the IC structure includes or is a part of input/output circuitry.

Example 35 provides the IC structure according to any one of examples 1-34, where the IC structure includes or is a part of an FPGA transceiver.

Example 36 provides the IC structure according to any one of examples 1-35, where the IC structure includes or is a part of an FPGA logic.

Example 37 provides the IC structure according to any one of examples 1-36, where the IC structure includes or is a part of a power delivery circuitry.

Example 38 provides the IC structure according to any one of examples 1-37, where the IC structure includes or is a part of a III-V amplifier.

Example 39 provides the IC structure according to any one of examples 1-38, where the IC structure includes or is a part of PCIE circuitry or DDR transfer circuitry.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a transistor comprising a channel region and a region comprising a doped semiconductor material, wherein the region is either a source region or a drain region of the transistor;
a gate structure coupled to the channel region, wherein the gate structure includes a gate electrode material and a first electrically conductive material;
a contact structure coupled to the region, wherein the contact structure includes a second electrically conductive material;
a gap between at least a portion of the gate structure and at least a portion of the contact structure; and
a liner material over at least a portion of a sidewall of the region below the contact structure, the liner material comprising aluminum and oxygen.

2. The IC structure according to claim 1, wherein a thickness of the liner material is less than about 5 nanometers.

3. The IC structure according to claim 1, wherein the liner material is a first liner material, and the IC structure further includes a second liner material over at least a portion of the sidewall of the region below the contact structure.

4. The IC structure according to claim 3, wherein the second liner material includes nitrogen.

5. The IC structure according to claim 4, wherein the second liner material further includes silicon.

6. The IC structure according to claim 3, wherein the second liner material is between the region and the first liner material.

7. The IC structure according to claim 3, wherein the second liner material is in contact with the region.

8. The IC structure according to claim 3, wherein the second liner material is in contact with the first liner material.

9. The IC structure according to claim 3, wherein a thickness of the second liner material is less than about 5 nanometers.

10. The IC structure according to claim 1, further comprising an interface material between the second electrically conductive material and the region.

11. The IC structure according to claim 10, wherein interface material includes titanium.

12. The IC structure according to claim 10, wherein the doped semiconductor material includes silicon and the interface material includes titanium and silicon.

13. An integrated circuit (IC) structure, comprising:
a first semiconductor material;
a second semiconductor material;
a first contact structure coupled to the first semiconductor material, wherein the first contact structure includes a first electrically conductive material;
a second contact structure coupled to the second semiconductor material, wherein the second contact structure includes a second electrically conductive material, wherein a distance between the first contact structure and the second contact structure is between about 3 nanometers and 50 nanometers, and at least a portion of a volume between the first contact structure and the second contact structure is a gap; and
a material over at least a portion of a sidewall of the first semiconductor material below the first contact structure, the material comprising aluminum and oxygen.

14. The IC structure according to claim 13, wherein a dopant concentration of the second semiconductor material is at least 100 times smaller than a dopant concentration of the first semiconductor material.

15. The IC structure according to claim 13, further comprising a transistor, wherein the first semiconductor material is either a source region or a drain region of the transistor.

16. The IC structure according to claim 15, wherein the second semiconductor material is a channel region of the transistor.

17. The IC structure according to claim 13, wherein a thickness of the material comprising aluminum and oxygen is below about 5 nanometers.

18. The IC structure according to claim 13, further comprising a material comprising silicon and nitrogen, wherein the material comprising silicon and nitrogen is between the first semiconductor material and the material comprising aluminum and oxygen.

19. A method of fabricating an integrated circuit (IC) structure, the method comprising:
providing a first semiconductor material;
providing a second semiconductor material;
providing a first contact structure coupled to the first semiconductor material, wherein the first contact structure includes a first electrically conductive material;
providing a second contact structure coupled to the second semiconductor material, wherein the second contact structure includes a second electrically conductive material, wherein a distance between the first contact structure and the second contact structure is between about 3 nanometers and 50 nanometers, and at least a portion of a volume between the first contact structure and the second contact structure is a gap; and
providing a material over at least a portion of a sidewall of the first semiconductor material below the first contact structure, the material comprising aluminum and oxygen.

20. The method according to claim 19, wherein a dopant concentration of the first semiconductor material is about 10²¹ dopants per cubic centimeter, and a dopant concentration of the second semiconductor material is at least 100 times smaller than the dopant concentration of the first semiconductor material.
